(19) United States
(12) Patent Application Publication
(10) Pub. No.: US 2023/0298947 A1
(43) Pub. Date: Sep. 21, 2023

(54) SYSTEMS AND METHODS FOR NON-CONTACT SEMICONDUCTOR TEMPERATURE MEASUREMENT

(71) Applicant: Trustees of Tufts College, Medford, MA (US)

(72) Inventor: Kevin Anthony Grossklaus, Medford, MA (US)

(21) Appl. No.: 18/187,284

(22) Filed: Mar. 21, 2023

Related U.S. Application Data
(60) Provisional application No. 63/322,046, filed on Mar. 21, 2022.

(51) Int. Cl. H01L 21/66

(52) U.S. Cl. CPC H01L 22/12

(57) ABSTRACT

Systems and methods for non-contact semiconductor temperature measurement involve reflecting light from a target semiconductor material. The reflected light is then used to identify a location of a spectral feature at an energy level that is above a band gap energy level of the target semiconductor material. The location of the spectral feature at the energy level that is above the band gap energy level of the target semiconductor material is used to determine the temperature of the target semiconductor material.

### CROSS-REFERENCE TO RELATED APPLICATIONS

This application claims the benefit of and priority to U.S. Provisional Patent Application No. 63/322,046, filed Mar. 21, 2022, the entirety of which is incorporated by reference herein.

### STATEMENT REGARDING FEDERALLY SPONSORED RESEARCH

Not applicable.

### BACKGROUND

The process of manufacturing semiconductors involves a variety of different complex steps. The process of manufacturing semiconductors also requires monitoring of different variables, including the temperature of various semiconductor materials. It can be difficult to accurately measure these temperatures, especially considering some of the challenging constraints present during the manufacturing process.

### SUMMARY OF THE DISCLOSURE

The present disclosure provides in one aspect a system including a light source, a target semiconductor material, a sensor that generates data responsive to acquiring light that is emitted by the light source and reflected from the target semiconductor material, and one or more circuits configured to process the data generated by the sensor to determine a temperature of the target semiconductor material based on a location of a spectral feature, wherein the location of the spectral feature is at an energy level that is above a band gap energy level of the target semiconductor material.

In another aspect, the present disclosure provides a method including reflecting light from a target semiconductor material, generating data including a reflectance spectrum responsive to acquiring the light reflected form the target semiconductor material, processing the data to identify a location of a spectral feature within the reflectance spectrum that is indicative of a temperature of the target semiconductor material, wherein the location of the spectral feature is at an energy level that is above a band gap energy level of the target semiconductor material, and determining the temperature of the target semiconductor material based on the location of the spectral feature.

In yet another aspect, the present disclosure provides a method including reflecting light from a target semiconductor material, generating data responsive to acquiring the light reflected from the target semiconductor material, processing the data to identify a location of a spectral feature, wherein the location of the spectral feature is at an energy level that is above a band gap energy level of the target semiconductor material, and determining a temperature of the target semiconductor material based on the location of the spectral feature.

These and other advantages and features of the present invention will become more apparent from the following detailed description of the present invention when viewed in conjunction with the accompanying drawings.

### DESCRIPTION OF THE DRAWINGS

FIG. 1 is an illustration showing an example system for non-contact temperature measurement of a target semiconductor material, in accordance with some embodiments of the present disclosure.

FIG. 2 is an example graph showing reflectance data that can be used in non-contact temperature measurement of a semiconductor material, in accordance with some embodiments of the present disclosure.

FIG. 3 is a flowchart showing an example process for non-contract temperature measurement of a first target semiconductor material, gallium antimonide, in accordance with some embodiments of the present disclosure.

FIG. 4 is an example graph showing reflectance data associated with a light source and a reference material, in accordance with some embodiments of the present disclosure.

FIG. 5 is an example graph showing raw reflectance data obtained from the first target semiconductor material, in accordance with some embodiments of the present disclosure.

FIG. 6 is another example graph showing reflectance data obtained from the first target semiconductor material, in accordance with some embodiments of the present disclosure.

FIG. 7 is another example graph showing reflectance data obtained from the first target semiconductor material, in accordance with some embodiments of the present disclosure.

FIG. 8 is an example graph showing the numerical first derivative of reflectance data obtained from the first target semiconductor material at different temperatures, in accordance with some embodiments of the present disclosure.

FIG. 9 is an example graph showing peak location as a function of temperature for the first target semiconductor material, in accordance with some embodiments of the present disclosure.

FIG. 10 is an example graph showing peak location as a function of temperature for use in generating a calibration curve for the first target semiconductor material, in accordance with some embodiments of the present disclosure.

FIG. 11 is an example graph showing temperature determined by peak location as a function of sample heater temperature for the first target semiconductor material, in accordance with some embodiments of the present disclosure.

FIGS. 12A-12D are example graphs showing processed reflectance data obtained from the first target semiconductor material at different temperatures, in accordance with some embodiments of the present disclosure.

FIG. 13 is an example table showing temperature data for the first target semiconductor material, in accordance with some embodiments of the present disclosure.

FIG. 14 is a flowchart showing an example process for generating a calibration curve for a specific type of target semiconductor material, in accordance with some embodiments of the present disclosure.

FIG. 15 is an example graph showing experimental spectroscopic ellipsometry data for the first target semiconductor material, in accordance with some embodiments of the present disclosure.

FIG. 16 is an example graph showing extracted optical constants for the first target semiconductor material, in accordance with some embodiments of the present disclosure.

FIG. 17 is an example graph showing calculated reflectance data for the first target semiconductor material, in accordance with some embodiments of the present disclosure.

FIG. 18 is an example graph showing processed reflectance data and corresponding peak maxima and zero crosses for the first target semiconductor material, in accordance with some embodiments of the present disclosure.

FIG. 19 is an example graph showing reflectivity data for different types of semiconductor materials, in accordance with some embodiments of the present disclosure.

FIG. 20 is an example table showing various data associated with different types of semiconductor materials, in accordance with some embodiments of the present disclosure.

FIG. 21 is an example graph showing reflectance data that can be used in non-contact temperature measurement of a second target semiconductor material, germanium, in accordance with some embodiments of the present disclosure.

FIG. 22 is an example graph showing extracted optical constants for the second target semiconductor material, in accordance with some embodiments of the present disclosure.

FIG. 23 is another example graph showing extracted optical constants for the second target semiconductor material, in accordance with some embodiments of the present disclosure.

FIG. 24 is an example graph showing peak location as a function of temperature for the second target semiconductor material, in accordance with some embodiments of the present disclosure.

FIGS. 25A-25D are additional example graphs showing processed reflectance data obtained from the second target semiconductor material at different temperatures, in accordance with some embodiments of the present disclosure.

FIG. 26 is an example graph showing extracted optical constants for a third target semiconductor material, indium arsenide, in accordance with some embodiments of the present disclosure.

FIG. 27 is another example graph showing extracted optical constants for the third target semiconductor material, in accordance with some embodiments of the present disclosure.

### DETAILED DESCRIPTION

Before the present disclosure is described in further detail, it is to be understood that the invention is not limited to the particular embodiments described. It is also to be understood that the terminology used herein is for the purpose of describing particular embodiments only, and is not intended to be limiting. The scope of the present invention will be limited only by the claims. As used herein, the singular forms “a”, “an”, and “the” include plural embodiments unless the context clearly dictates otherwise.

It should be apparent to those skilled in the art that many additional modifications beside those already described are possible without departing from the inventive concepts. In interpreting this disclosure, all terms should be interpreted in the broadest possible manner consistent with the context. Variations of the term “comprising” should be interpreted as referring to elements, components, or steps in a non-exclusive manner, so the referenced elements, components, or steps may be combined with other elements, components, or steps that are not expressly referenced. Embodiments referenced as “comprising” certain elements are also contemplated as “consisting essentially of” and “consisting of” those elements.

In places where ranges of values are given, this disclosure explicitly contemplates other combinations of the lower and upper limits of those ranges and sub-ranges that fall therein, which may not be explicitly recited. For example, recitation of a value between 1 and 10 also contemplates values, e.g., from 2 to 9, from 2 to 8, or from 3 to 4. Ranges identified as being “between” two values are inclusive of the end-point values. For example, recitation of a value between 1 and 10 includes the values 1 and 10.

Features of this disclosure described with respect to a particular method, apparatus, composition, or other aspect of the disclosure can be combined with, substituted for, integrated into, or in any other way utilized with other methods, apparatuses, compositions, or other aspects of the disclosure, unless explicitly indicated otherwise or necessitated by the context. For clarity, an aspect of the invention described with respect to one method can be utilized in other methods described herein, or in apparatuses or with compositions described herein, unless context clearly dictates otherwise.

During the fabrication process, the ability to determine the temperature of semiconductor materials is critical to controlling the outcome of the fabrication process. However, measurement of material temperature by contact sensors (e.g., thermocouples, resistance temperature detectors (RTDs), etc.) often is not feasible within a deposition or processing system, and thus non-contact temperature measurement methods are necessary for certain applications. Some non-contact temperature measurement techniques can experience undesirable effects such as poor accuracy or poor repeatability due to error sources such as interference from different elements of the processing system, environmental light sources, and variation in run-to-run material properties. Additionally, some non-contact temperature measurement techniques may either be incapable of measuring temperature of semiconductor materials at low temperature (e.g., 400° C. and below) or very inaccurate when measuring temperature of semiconductor materials at low temperature. As semiconductor process technology evolves, more and more low temperature applications arise.

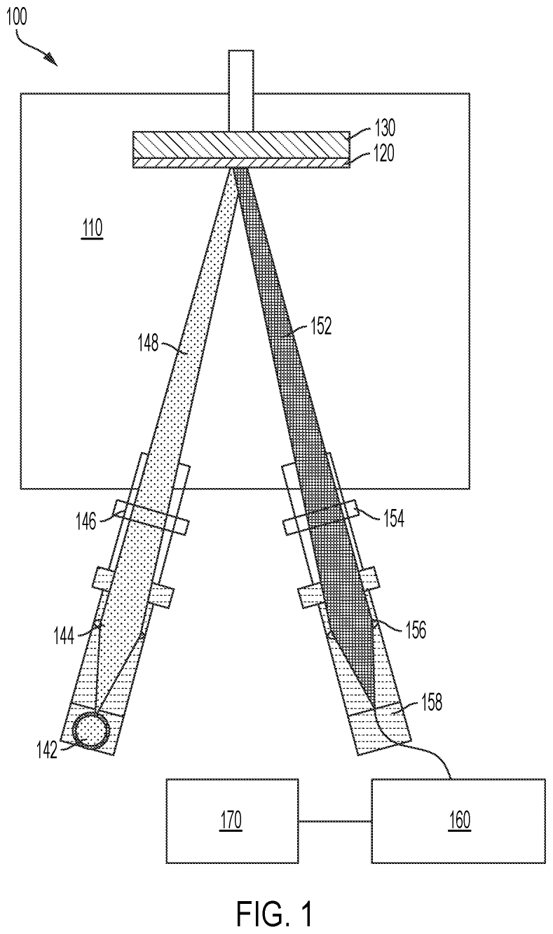

Referring to FIG. 1, a system 100 for non-contact temperature measurement of a target semiconductor material is shown, in accordance with some embodiments of the present disclosure. System 100 generally can be used to measure without physical contact the temperature of materials with sharp, above band gap spectral reflectance features that show repeatable shifts with temperature. These materials include, but are not limited to, some of the most commonly used and industrially important inorganic semiconductors such as silicon (Si), germanium (Ge), gallium arsenide (GaAs), indium arsenide (InAs), indium phosphide (InP), indium antimonide (InSb), and gallium antimonide (GaSb). These materials show sharp features in their reflectance spectra corresponding to critical points in their dielectric functions indicative of electronic band gaps and band transitions, and such features have a known or readily determinable dependence on material temperature. System 100 can also be used to determine the temperature of semiconductor thin films and other types of materials.

The ability to measure the temperature of semiconductor materials without contacting the semiconductor materials directly is critical in achieving accurate and repeatable deposition and processing in a variety of applications including thing film deposition, epitaxial growth, and heat treatment, among others. System 100 can be used to provide accurate and repeatable temperature measurement over a broad temperature range (including lower temperatures), and the temperature measurement process performed using system 100 may replace or complement other non-contact temperature measurement technologies.

System 100 is shown to include a deposition chamber 110. Deposition chamber 110 can be implemented in a variety of ways. For example, deposition chamber 110 can be a chamber used in a molecular-beam epitaxy (MBE) process for thin film deposition of single crystals and crystalline structures in a semiconductor manufacturing process. Deposition chamber 110 can also be a chamber used in chemical vapor deposition (CVD), atomic layer deposition (ALD), physical vapor deposition (PVD), pulsed laser deposition (PLD), vapor-phase epitaxy (VPE), liquid-phase epitaxy (LPE), or solid-phase epitaxy (SPE) processes, among others. Deposition chamber 110 can be used in a variety of different types of epitaxy processes, including homoepitaxy, hetroepitaxy, homotopotaxy, heterotopotaxy, grain-to-grain epitaxy, and pendeo-epitaxy processes, among others. Deposition chamber 110 can also be used for various aspects of a semiconductor manufacturing process including etching, ion implant, and polishing steps. The pressure of deposition chamber 110 can be controlled, for example at high vacuum or ultra-high vacuum pressure levels.

System 100 is also shown to include a target semiconductor material 120. Target semiconductor material 120 can be implemented using a variety of different materials, including wafer substrate materials such as silicon (Si), germanium (Ge), gallium arsenide (GaAs), indium arsenide (InAs), gallium antimonide (GaSb), indium antimonide (InSb), and indium phosphide (InP), as well as buffer layer films such as indium 0.53 gallium 0.47 arsenide (In0.53Ga0.47As) and other films that can be deposited on a wafer or substrate. Target semiconductor material 120 is generally thick enough for light to reflect from it without substantially reflecting from materials underneath or otherwise surrounding target semiconductor material 120, however the techniques described in the present disclosure may be applicable to a variety of materials with varying levels of thickness. Target semiconductor material 120 also generally exhibits a characteristic in that a spectral feature (e.g., peak) can be identified at an energy level above the band gap level using reflectance data generated based on light that is reflected from target semiconductor material 120.

System 100 is also shown to include a sample heater 130. Sample heater 130 generally provides heat to target semiconductor material 120 during the manufacturing process. Sample heater 130 can be implemented in a variety of ways, including as a ring type heater, a platen type heater, a cable type heater, a flexible type heater, a pedestal type heater, and using brazed heater plates, among other types of heater implementations. Sample heater 130 generally provides heating for semiconductor materials in deposition chamber 110 to facilitate the semiconductor process, such as heat for use in a molecular-beam epitaxial growth process.

System 100 is also shown to include a light source 142, light source optics 144, a viewport 146, and directed light 148. Light source 142 can be implemented in a variety of manners, for example light source 142 can be a broad-spectrum light source. Light emitted by light source 142 can be infrared or non-infrared light, including ultraviolet light. Light source optics 144 are components that can be configured to modify the photons emitted by light source 142 in some way depending on the intended application. Viewport 146 is a component that provides a means for light to enter deposition chamber 110. Directed light 148 is light that enters deposition chamber 110 and is directed at target semiconductor material 120. System 100 is also shown to include reflected light 152, a viewport 154, collection optics and filters 156, and an input 158. Reflected light 152 is light that is reflected from target semiconductor material 120 based on directed light 148. Viewport 154 is a component that provides a means for light to exit deposition chamber 110. Collection optics 156 are components that can be configured to modify reflected light 152 in some way depending on the intended application. Input 158 provides a path for reflected light 152 to be captured by a spectrometer 160, discussed in more detail below.

System 100 is also shown to include spectrometer 160 and a computer 170. Spectrometer 160 is generally an optical system capable of measuring the spectrum of input light, and it receives reflected light 152 and measures the spectrum of reflected light 152. Spectrometer 160 can be implemented in a variety of manners (e.g., spectrometer, spectrophotometer, spectrograph, spectroscope, spectrum analyzer, generally a sensor), including as a multi-component setup, such as a monochromator paired with an appropriate wide band photodetector, for example. As another example, a monochromator can be placed after light source 142 at or before light source optics 144, directed (input) light 148 can be varied across known wavelengths, and the intensity of the known wavelengths can be measured following reflection. Various setups are possible where this type of approach is taken, namely scanning the wavelength of the input light in a known way and measuring the output at each individual wavelength step rather than measuring a broad spectrum of the reflected light. Spectrometer 160 can include one or more circuits configured generate data including the intensity of reflected light 152 at different wavelengths. Computer 170 can be implemented using a variety of different hardware and network configurations, and generally receives data from spectrometer 160. One or more circuits of computer 170 can be configured to generate a reflectance spectrum for target semiconductor material 120 based on reflectance data generated by spectrometer 160, and to process data by executing scripts and/or one or more software packages for determining the location of various spectral features, determining the temperature of target semiconductor material 120, generating and storing calibration curves, and other functions as discussed in more detail below. The components of system 100 can be configured in a variety of ways depending on the specific application, and these components can be removed and/or replaced with different components in certain applications. System 100 provides an example implementation of a system for carrying out the non-contact temperature measurement techniques described in the present disclosure.

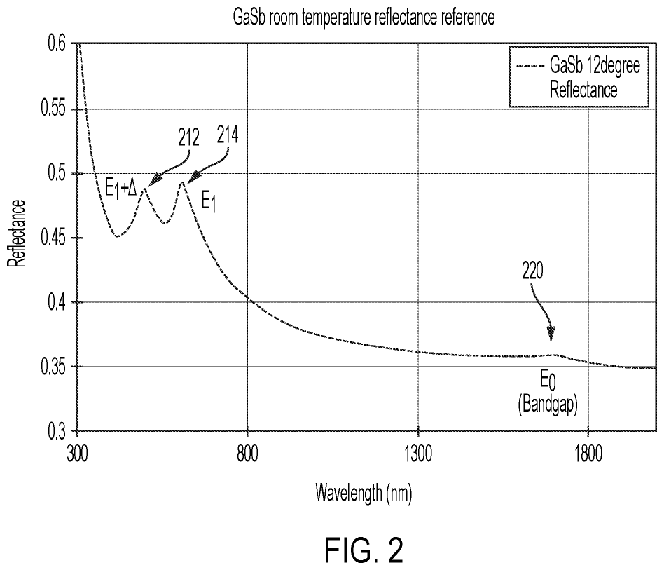

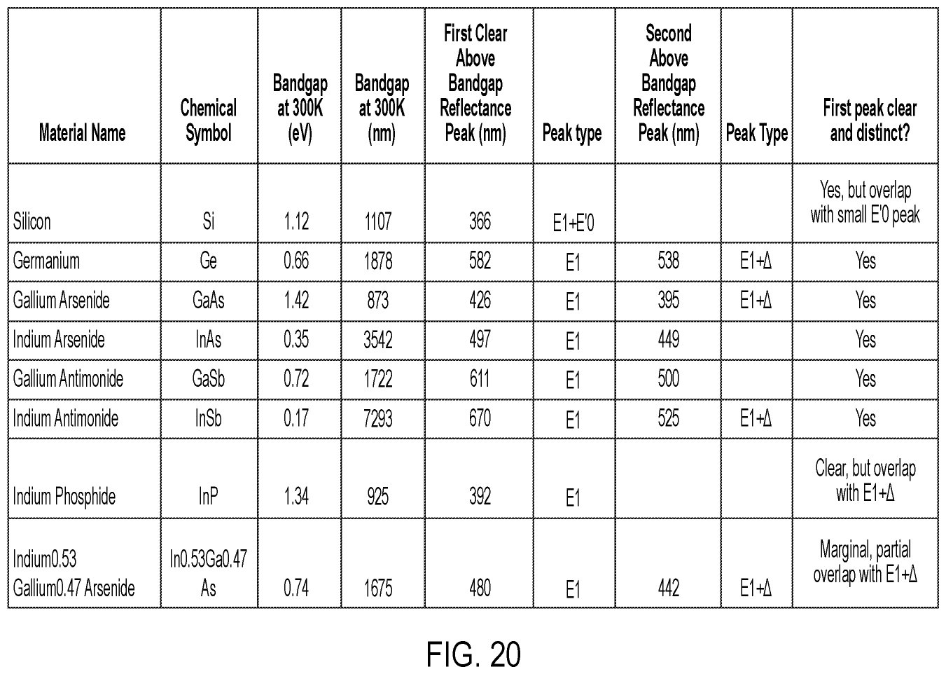

Referring to FIG. 2, an example graph of reflectance data that can be used in non-contact temperature measurement of a semiconductor material is shown, in accordance with some embodiments of the present disclosure. The graph of FIG. 2 shows a spectral reflectance spectrum associated with a target semiconductor material of gallium antimonide at room temperature and a 12-degree angle of incidence. The reflectance of the gallium antimonide material is plotted on the y-axis, and wavelength is plotted on the x-axis. In the graph of FIG. 2, two higher energy above band gap spectral features can be seen: both a spectral feature 212 and a spectral feature 214. Additionally, a lower energy bandgap spectral feature 220 can also be seen in the graph of FIG. 2. The location of the above band gap (or critical points indicating higher order band transitions) spectral features 212 and 214 have a repeatable dependence on temperature and are large features in the reflectance/reflectivity spectrum of many semiconductor materials. Based on the specific semiconductor material, the types of spectral features identified as indicative of temperature may vary. For example, spectral feature 214 as shown in FIG. 2 is found at an energy level E₁, whereas spectral feature 212 is found at an energy level with some delta with respect to E₁, reflected as E₁+Δ. Spectral features (e.g., peaks, transitions) can also be found at locations such as a derivative of the band gap energy level (E′₀) for different materials. Additional spectral features that are higher energy non-bandgap spectral features, but are not peaks, can be identified using techniques including using the first or second derivative of reflectance data, and can be indicative of temperature depending on the material. Examples of spectral features of interest and associated data is provided in FIG. 20 and discussed in more detail below.

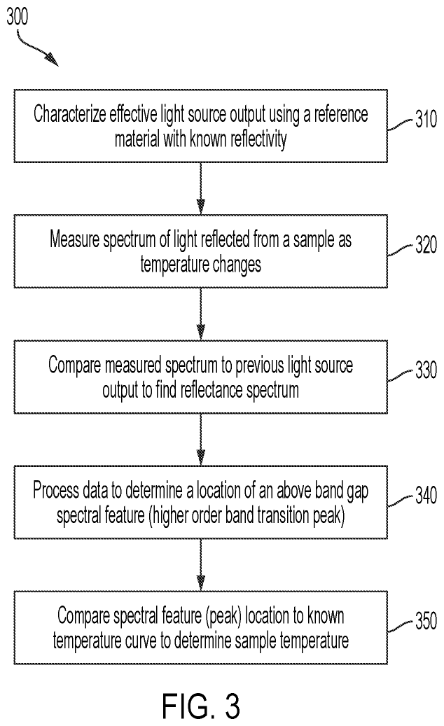

Referring to FIG. 3, a flowchart illustrating an example process 300 for non-contact measurement of semiconductor materials is shown, in accordance with some embodiments of the present disclosure. Process 300 can be performed using system 100 as described above, for example. Process 300 generally involves spectroscopy of broad spectrum light specularly reflected from a material surface. Implementations of process 300 can include a broad-spectrum light source that can either be projected onto a material and then the reflected spectrum can be analyzed as a whole, or a narrow band of light can be varied over a broad wavelength range and the reflection at each step can be measured and assembled into a reflected spectrum.

Once collected, the spectrum of reflected light can be processed to find the reflectance spectrum (material reflectance vs wavelength) of the target semiconductor material. Spectrum processing can include comparison to a known output of the light source or comparison to reflectance from a known reflectance standard. The reflectance from a known standard can be used to back-out the effective spectral intensity (intensity as a function of light wavelength) of the light source. Accordingly, it may not be necessary to determine the absolute intensity of the light source, because only the relative intensity at each wavelength may be needed. Once the effective spectral intensity of the light source has been determined, it can then be compared to the spectrum of light reflected from the target semiconductor material to determine the effective spectral reflectance of the material. Additional data processing steps to determine the final material reflectance spectrum may be included, such as subtraction of spectrometer or photodetector background (spectrometer function or dark background) and background light subtraction (light noise from another source).

After the material reflectance spectrum has been found, it can be examined for sharp or otherwise distinct features within the spectral range of the optical system used and above the band gap of the material of interest. These features can be critical points indicating higher energy band transitions (electronic band transitions in a semiconductor larger than the band gap) or other features that strongly affect the reflectance of the material. The wavelength of these distinct or sharp reflectance features can be accurately determined using data analysis techniques such as using the numerical first derivative to find the location of a peak maxima or using the numerical second derivative to find the location of an inflection point. In a suitable target semiconductor material, the wavelengths of these features have a strong dependance on material temperature, and thus the location of the feature can indicate the absolute temperature of the material. The temperature dependence of optical features in the material reflectance spectrum can be taken from reference sources for well-known materials (e.g., band transition critical point wavelengths for inorganic semiconductors) or determined by ex-situ experimental measurement. By tracking the wavelength of sharp and/or distinct features in the reflectance spectrum of the target semiconductor material and comparing that to its known wavelength vs. temperature dependence, the temperature of the target semiconductor material can be determined.

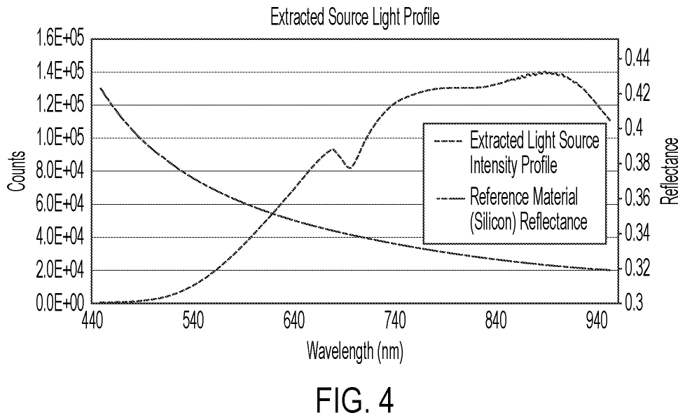

Process 300 is shown to include characterizing an effective light source output using a reference material with known reflectivity (310). For example, the actual output of light source 142 may be determined using silicon as a reference material, as illustrated in the example graph of FIG. 4. In the graph of FIG. 4, both the spectral counts and reflectance are plotted on the y-axis, and wavelength is plotted on the x-axis. The reflectance spectrum of both light source 142 as well as the reference silicon material are shown. It is important to understand the actual output of light source 142 to understand how the light reflected from target semiconductor material 120 changes as the temperature of target semiconductor material 120 changes. The use of a reference material like silicon can be helpful in characterizing the output of light source 142. A variety of different reference materials can be used to characterize the output of light source 142 in this manner.

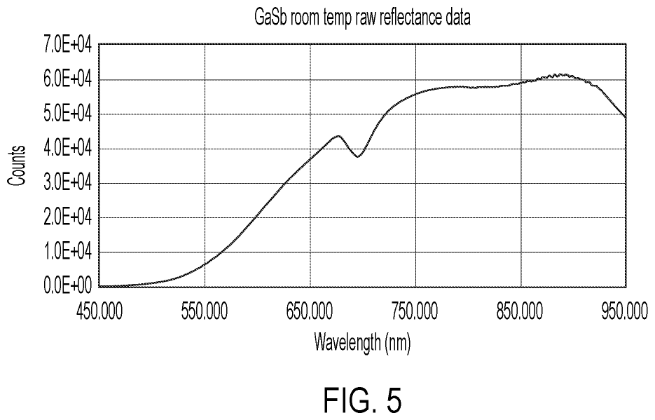

Process 300 is also shown to include measuring a spectrum of light reflected form a sample as temperature changes (320). For example, in the graph of FIG. 5, raw reflectance data obtained from a gallium antimonide sample is shown. In the graph of FIG. 5, spectral counts are plotted on the y-axis and wavelength is plotted on the x-axis, and the data is collected at room temperature. Raw reflectance data can be obtained using spectrometer 160, for example, and is generated based on light reflected from target semiconductor material 120 (reflected light 152). The properties shown in the raw reflectance data can vary based on the type of semiconductor material light is reflected from, among other factors depending on the intended application. It may be difficult to identify spectral features indicative of temperature from the raw data, whereas further processing can be used to identify these spectral features more easily.

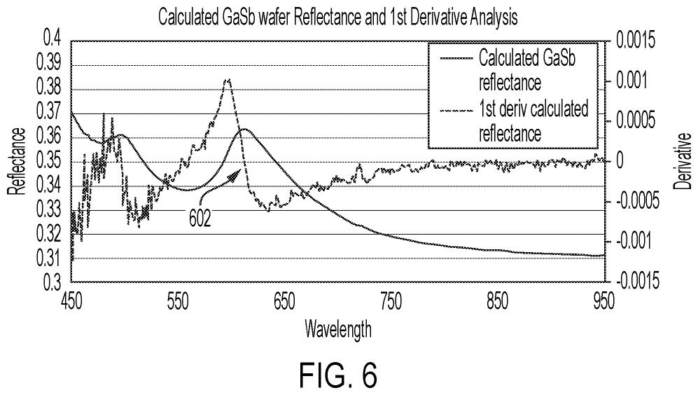

Process 300 is also shown to include comparing the measured spectrum to a previous light source output to find the reflectance spectrum (330). For example, in the graph of FIG. 6, calculated reflectance data from the gallium antimonide sample is shown along with the calculated numerical first derivative of this reflectance data. In the graph of FIG. 6, both reflectance and the value of the numerical first derivative are plotted on the y-axis, and wavelength is plotted on the x-axis. At point 602 in the graph of FIG. 6, the numerical first derivative reaches zero, which is indicative of a location of an above bang gap spectral feature (such as spectral feature 212 or spectral feature 214). By comparing reflected light 152 to a reference in this manner, the reflectance spectrum shown for example in FIG. 6 can be generated.

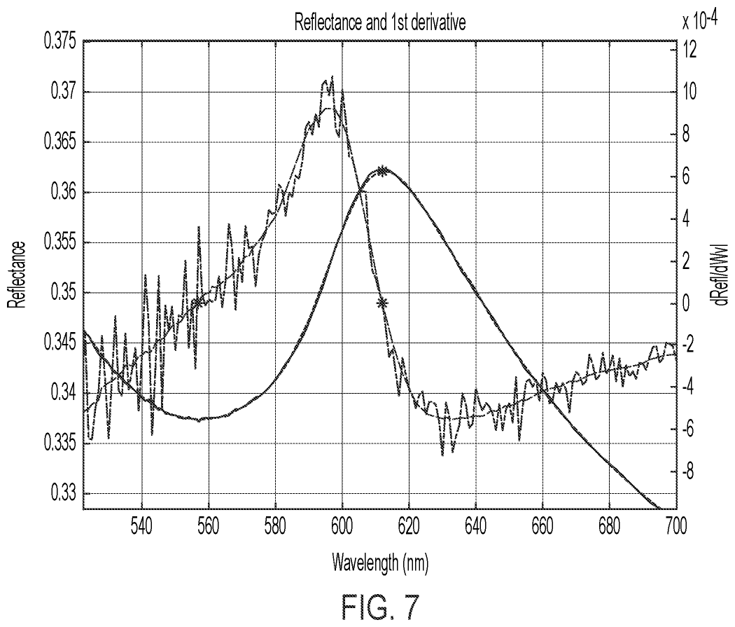

Process 300 is also shown to include processing data to determine a location of an above band gap spectral feature, or critical point peak indicating a higher order band transition (340). For example, as shown in the graph of FIG. 7, the data from FIG. 6 has been filtered to obtain a smoothed fit and a script has been used to identify the location of the above band gap spectral feature (such as spectral feature 212 or spectral feature 214) on both curves. In the graph of FIG. 7, both reflectance (left) and the value of the numerical first derivative (right) with respect to wavelength are plotted on the y-axis, and wavelength is plotted on the x-axis. The location where the numerical first derivative reaches zero is indicative of the location of the spectral feature. In the graph of FIG. 7, this occurs at a wavelength of about 615 nanometers.

Process 300 is also shown to include comparing the location of the spectral feature (peak) to a known temperature curve (calibration curve) to determine a temperature of the sample (350). A calibration curve (peak location vs. temperature curve) can be generated in various ways, such as using process 1400 as described in more detail below, in order to convert the identified location of the above band gap spectral feature to a temperature of target semiconductor material 120, which in this case is a gallium antimonide sample. The calibration curve used to determine the temperature of target semiconductor material 120 varies depending on the specific type of material used. Software can be used to determine the temperature of target semiconductor material 120 more easily and efficiently upon identifying the location of the spectral feature.

Process 300 can rely on optically tracking the higher energy, above band gap critical points and electronic transitions in semiconductor materials, and can do so using direct specular reflectance spectra. By using direct specular reflectance rather than an approach such as diffuse reflectance, optical emission from the target semiconductor material, or transmission of light through the target semiconductor material, process 300 can be less sensitive to other light sources in the material processing system. Such sources of background light in an inorganic semiconductor deposition system, for example, may be unavoidable and difficult to minimize, so lessening their effect on the accuracy of a temperature measurement is desirable. Alternative approaches may suffer significant negative effects due to other light sources in the environment surrounding the target semiconductor material.

By tracking higher energy band transitions or other spectral features, process 300 can avoid many of the problems associated with attempting to determine temperature by tracking material band gap energies or by measuring reflected light intensities only. Process 300 does not rely on the intensity of reflected light to determine temperature, but rather tracks the location of a spectral feature. Accordingly, process 300 is less sensitive to variations in the temperature measurement system (e.g., changes in light source intensity) and to changes in material surface that affect reflectance (e.g., surface roughness). By tracking above band gap, higher energy spectral features, process 300 avoids the difficulties of techniques that track band edge energy. Light interference and transmission effects in the near band edge reflectance spectrum can make band edge energy difficult to determine. These effects will not be present at higher energies due to strong light absorption in the target semiconductor material at those energies. Higher energy transitions also are not as strongly affected by variations of some common semiconductor properties. Doping of a semiconductor can result in significant broadening of the band gap, which can make determining its location difficult. The band gaps of indirect semiconductors, such as silicon and germanium, are inherently broad and therefore can be difficult to track accurately. However, higher energy transitions in both silicon and germanium, as well as other semiconductor materials, are sharp and easily identifiable, enabling their use for temperature measurement using process 300. Those same high energy features remain visible at low temperatures and in many cases become more distinct and easier to track.

Process 300 can provide advantages when compared to some alternative approaches. The higher order optical transitions of many materials lie in the near-ultraviolet, visible, and near-infrared spectral range. Accordingly, process 300 is compatible with the most common window materials and light detector systems available. Temperature can be determined by referencing measured spectra relative to known spectra using process 300, rather than by straight signal intensity comparison. As such, process 300 can be less sensitive to variations in some material properties and day-to-day variations in the condition of the processing system. For example, techniques that measure reflected intensity directly can be highly sensitive to changes in material surface condition, whereas process 300 can be less affected by changes in surface roughness and thus can still allow for temperature measurement of both smooth and rough surfaces. Process 300 can track features in the reflectance spectra for semiconductors that show a repeatable and consistent shift with temperature, and that become sharper and more distinct at lower temperatures, thereby enabling temperature measurement at lower temperatures. As a result of tracking higher energy optical features in the reflectance spectra, process 300 may only measure the front surface and near surface temperature of the target semiconductor material, as opposed to some other approaches where there is a significant difference between the back side, bulk, and front surface temperatures of a material (i.e., there is a significant front-to-back temperature gradient). Since process 300 can track higher energy optical features in the reflectance spectrum where optical absorption in the material can be relatively high, it can avoid spectral features such as interference fringes that may be present in the energy range near the material band gap and below it. This aspect of process 300 can be especially useful when measuring the temperature of thin films on a substrate, such as alloy film In0.53Ga0.47As. Process 300 can be used to measure the temperature of a variety of known films grown on different substrates, including various types of buffers. Since process 300 can track higher energy optical features that remain visible even with material property variation, it can still track the temperature of many semiconductor materials with property variations that strongly affect their band gap energies (lower energy transitions) or broad spectrum absorption. This includes the ability to measure the temperature of small band gap materials and highly doped materials that may confound other measurement techniques. Since process 300 can track a distinct spectral feature, not intensity, it can be relatively insensitive to other variations in the processing system, such as variations in the material angle. Other approaches can be highly sensitive to any variation in the target semiconductor material angle relative to the temperature measurement apparatus.

Process 300 can be used by a variety of individuals and entities that need to accurately measure the temperature of semiconductor materials during processing. Such entities can include manufacturers of semiconductor processing equipment that rely on accurate temperature measurement for process repeatability and/or accuracy. Such individuals and/or entities can also include users of semiconductor processing equipment, especially those owning systems that do not have an effective and accurate way of measuring semiconductor material temperature, including manufacturers and research and development entities. The techniques described in the present disclosure may enable manufacturing of alloy systems such as SiGeSn and GaSbBi at lower temperatures that can produce better results than when these alloys are manufactured at higher temperatures. Production of these alloys at higher temperatures can result in changes in alloy composition, among other undesirable properties.

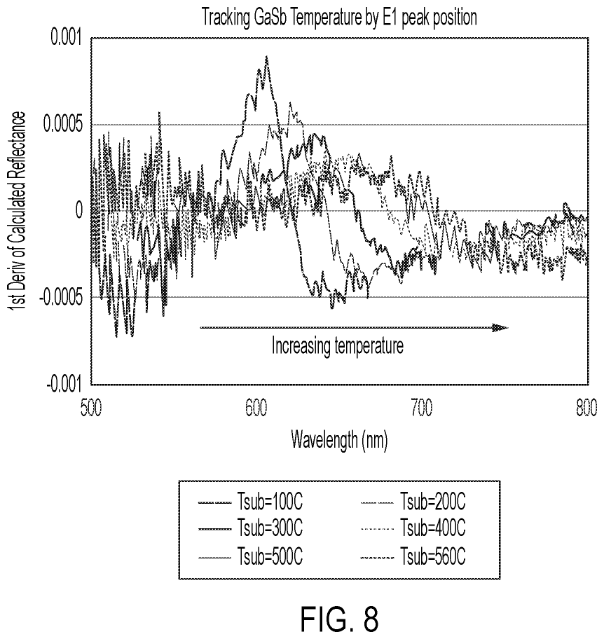

Referring to FIG. 8, an example graph of the numerical first derivative of reflectance data obtained from a gallium antimonide at different temperatures is shown, in accordance with some embodiments of the present disclosure. In the graph of FIG. 8, the value of the numerical first derivative of the calculated reflectance data for a gallium antimonide sample is plotted on the y-axis and wavelength is plotted on the x-axis. As shown, the direction of increasing temperature is in the direction of increasing wavelength along the x-axis. The graph of FIG. 8 is similar to the graphs of FIG. 6 and FIG. 7, however the graph of FIG. 8 illustrates how the numerical first derivative of the calculated reflectance data for a gallium antimonide sample varies with temperature. In the graph of FIG. 8, the numerical first derivative of the calculated reflectance data for a gallium antimonide sample is shown at sample heater temperatures of 100° C., 200° C., 300° C., 400° C., 500° C., and 560° C. The graph of FIG. 8 shows that the numerical first derivative of the calculated reflectance data for a gallium antimonide sample does indeed vary with temperature, and accordingly this can be useful in measuring the temperature of the gallium antimonide sample.

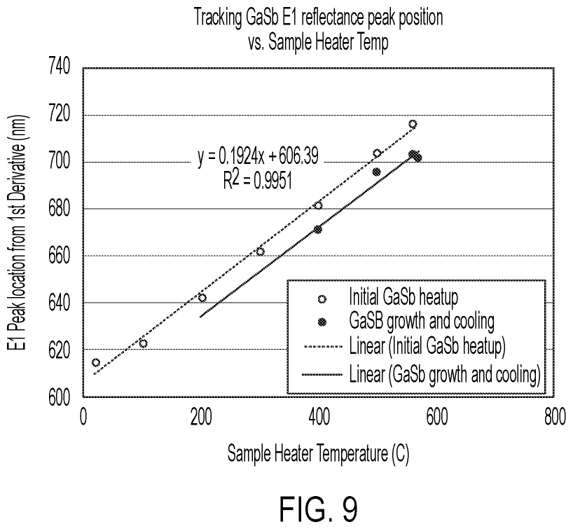

Referring to FIG. 9, an example graph showing peak location as a function of sample heater temperature is shown, in accordance with some embodiments of the present disclosure. In this specific example, the target semiconductor material 120 is still a gallium antimonide sample, and the sample heater temperature is the temperature of sample heater 130. In the graph of FIG. 9, the peak location wavelength is plotted on the y-axis, whereas the sample heater temperature is plotted on the x-axis. Each plotted peak location corresponds to a point where the numerical first derivative of the calculated reflectance data for the gallium antimonide sample is zero at the given sample heater temperature. Separate plots are shown in FIG. 9 for the initial heat up of the gallium antimonide sample as well as the growth and cooling of the gallium antimonide sample. It can again be seen from the graph of FIG. 9 that the peak location (e.g., the location of the above band gap spectral features such as spectral feature 212 or spectral feature 214) does vary with temperature, and it does so in a generally linear relationship. This data is again indicative that the peak location found using the numerical first derivative of the calculated reflectance data for the gallium antimonide sample can be useful in measuring the temperature of the gallium antimonide sample.

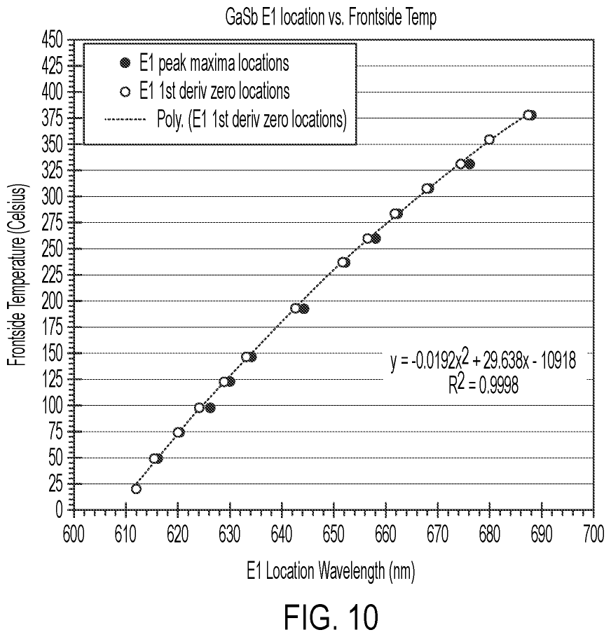

Referring to FIG. 10, an example graph showing peak location as a function of temperature for use in generating a calibration curve is shown, in accordance with some embodiments of the present disclosure. In this specific example, the target semiconductor material 120 is still a gallium antimonide sample, and the temperature is the frontside temperature of the gallium antimonide sample. In the graph of FIG. 10, the known frontside (top surface) temperature of gallium antimonide is plotted on the y-axis, and the peak location wavelength is plotted on the x-axis. The data shown in FIG. 10 can be used to generate a calibration curve (reference curve) for determining the unknown temperature of a gallium antimonide sample based on its measured peak location. Separate plots are shown for the locations where the numerical first derivative of the calculated reflectance data for the gallium antimonide sample is zero and the actual peak maxima locations, which are similar. A second-degree curve fit is shown connecting the locations where the numerical first derivative of the calculated reflectance data for the gallium antimonide sample is zero.

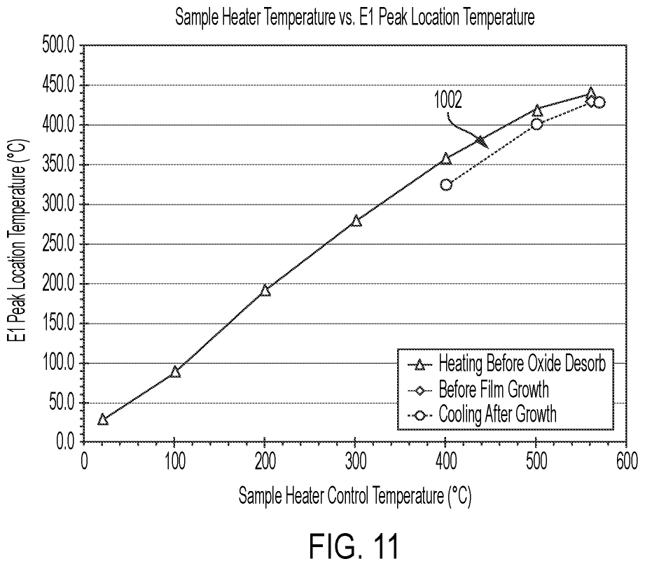

Referring to FIG. 11, an example graph showing temperature determined by peak location as a function of sample heater temperature is shown, in accordance with some embodiments of the present disclosure. In the graph of FIG. 11, the peak location temperature is plotted on the y-axis, and the sample heater temperature is plotted on the x-axis. Moreover, separate plots are shown for sample heating that occurs before oxide desorption, before film growth, and after film growth. The data shown in the graph of FIG. 11 can be obtained using a specific example where the target semiconductor material 120 is a gallium antimonide sample that is heated and cooled using sample heater 130. The peak locations shown in FIG. 11 track smoothly with the temperature of sample heater 130, with a resolution varying between about ±6° C. at lower temperatures and ±3° C. at higher temperatures.

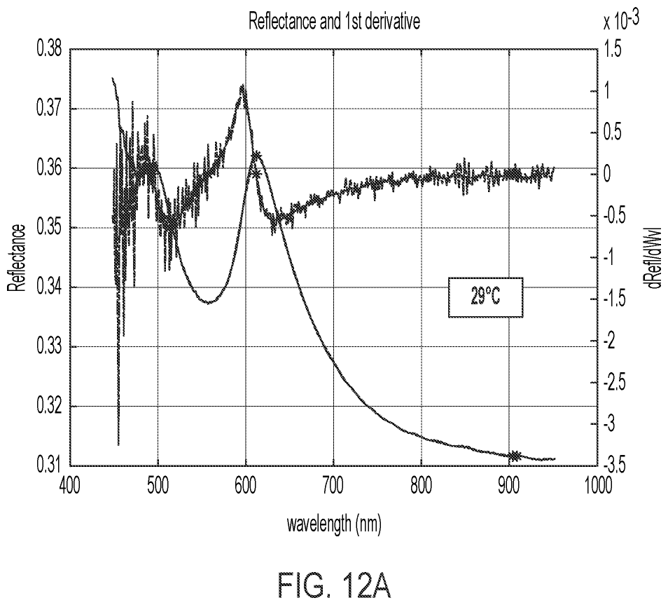

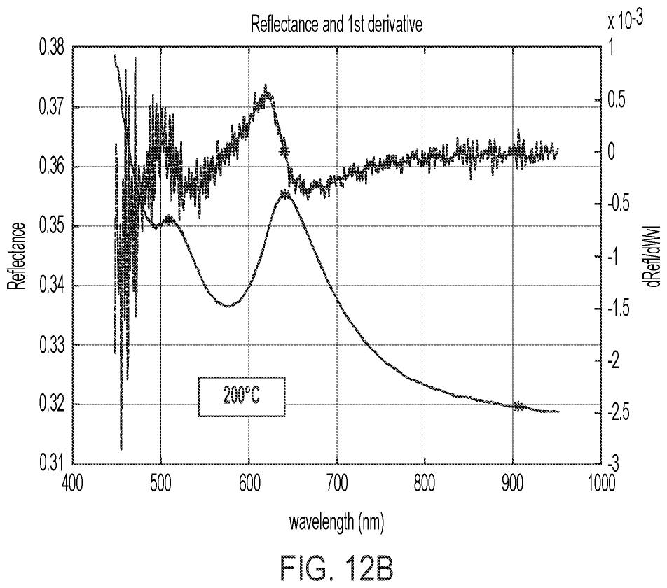

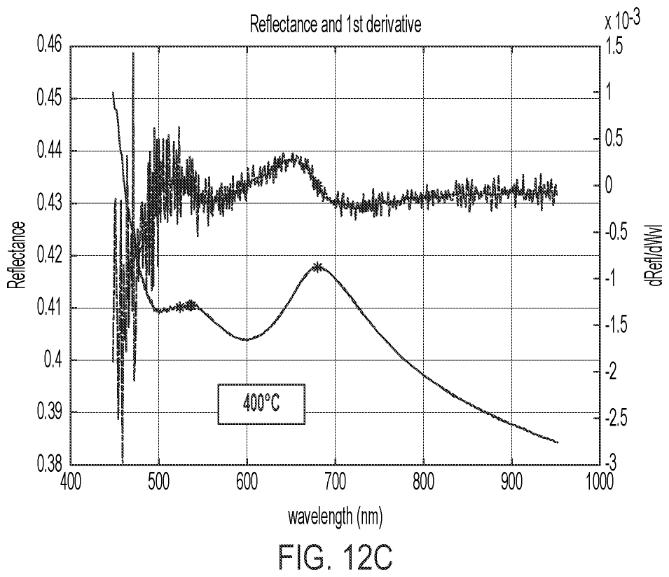

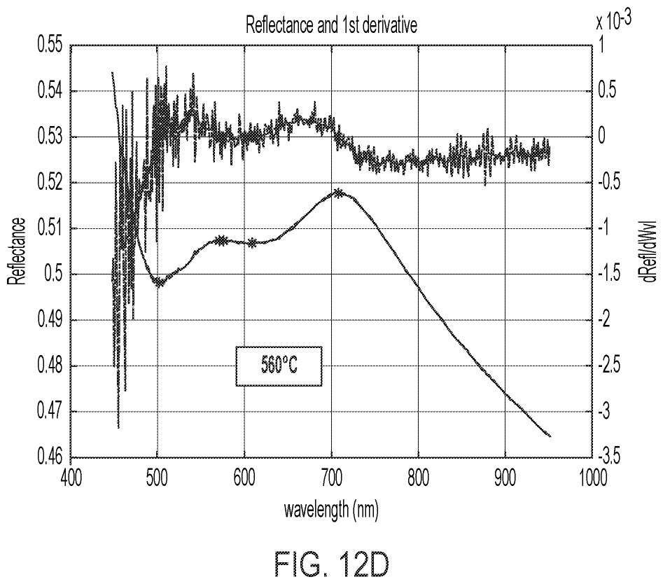

Referring to FIGS. 12A-12D, a series of graphs showing processed reflectance data obtained from a target semiconductor material at different temperatures is shown, in accordance with some embodiments of the present disclosure. The data shown in FIGS. 12A-12D can be obtained using the same heating and cooling process for a gallium antimonide sample as used to obtain the example data shown in the graph of FIG. 11, for example. In the graphs of FIGS. 12A-12D, both the calculated reflectance data of the gallium antimonide sample and the calculated numerical first derivative of the calculated reflectance data of the gallium antimonide sample are plotted on the y-axis, and wavelength is plotted on the x-axis. Like the data shown in FIG. 7, the data shown in FIGS. 12A-12D has been filtered, and a script has been used to identify locations of above band gap spectral features (such as spectral feature 212 or spectral feature 214). FIG. 12A shows data corresponding to a sample heater temperature of 29° C., FIG. 12B shows data corresponding to a sample heater temperature of 200° C., FIG. 12C shows data corresponding to a sample heater temperature of 400° C., and FIG. 12D shows data corresponding to a sample heater temperature of 560° C. It can be seen from the data shown in FIGS. 12A-12D that when using the reflectance analysis described in the present disclosure, the peak locations are clearly identifiable at each temperature. Some alternative approaches to measuring temperature of a target semiconductor material, in contrast, may be incapable or inaccurate at low temperatures, such as at 29° C. or at 200° C.

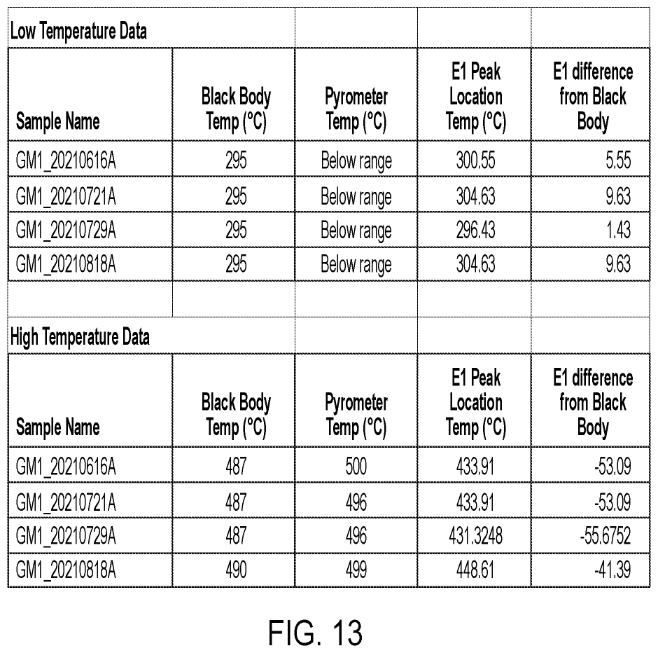

Referring to FIG. 13, an example table of temperature data for a target semiconductor material is shown, in accordance with some embodiments of the present disclosure. The table of FIG. 13 shows data collected for four different samples of gallium antimonide (target semiconductor material 120) both at low temperature and at high temperature. For each sample, temperature data obtained using the non-contact temperature measurement technique of process 300 is compared to temperature data obtained using two other non-contact temperature measurement techniques: using a black body curve fit technique and using a pyrometer (optical pyrometry). The low temperature data is associated with a measured black body temperature of around 295° C., whereas the high temperature data is associated with a measured black body temperature of around 487° C. The low temperature data as shown in FIG. 13 is collected at around the lowest possible temperature the black body curve fit technique as capable of measuring and, as shown, this low temperature is outside the sensible range of the pyrometer. However, the location of the high energy spectral feature (e.g., spectral feature 214) can be identified at the low temperature and used to measure the temperature of the gallium antimonide sample.

As shown in the table of FIG. 13, at low temperature, the location of the spectral feature identified using process 300 may have some variance from the measured black body temperature of target semiconductor material 120. However, this variation is generally repeatable within ±8° C. and agrees with the black body temperature to within 10° C. While there is some inherent error in the experimental setup used to collect this data, it still demonstrates the effectiveness of process 300 in determining the temperature of the gallium antimonide samples. At high temperature, the location of the spectral feature identified using process 300 is generally repeatable within ±16° C. but has significant disagreement of above 41° C. The disagreement in this data generally arises from the inability to collect ex-situ reference data above 380° C. in the experimental setup, causing a need for extrapolation with no guarantee of accuracy, as well as the expected broadening of the peak location (spectral feature) and noise in the experimental setup. However, the data shown in FIG. 13 generally demonstrates that process 300 can be effective, especially at lower temperatures.

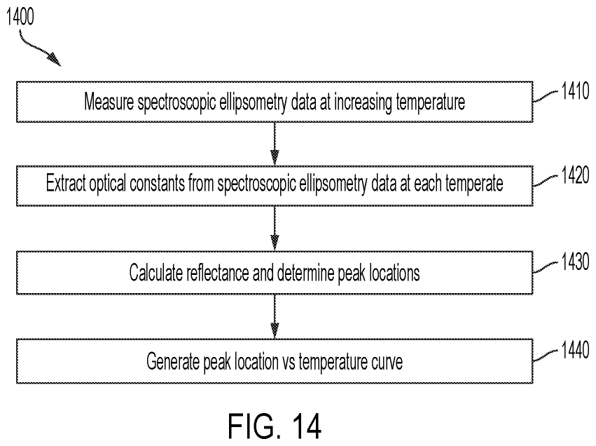

Referring to FIG. 14, a flowchart illustrating an example process 1400 for generating a calibration curve for a specific type of target semiconductor material is shown, in accordance with some embodiments of the present disclosure. Process 1400 generally uses methods such as spectroscopic ellipsometry to measure the reflectivity (optical constants) as a function of known temperature for a given target semiconductor material to generate a calibration curve. The calibration curve can then be used during process 300 to determine the unknown temperature of a sample semiconductor material. Process 1400 can be adapted depending on the application to generate different kinds of calibration curves for different implementations. For example, a calibration curve could be found without using spectroscopic ellipsometry by measuring sample reflectance at known temperatures. Such a process could be represented generally with the steps of measuring reflectance at increasing temperature, determining peak locations in the reflectance data, and generating a peak location vs temperature curve.

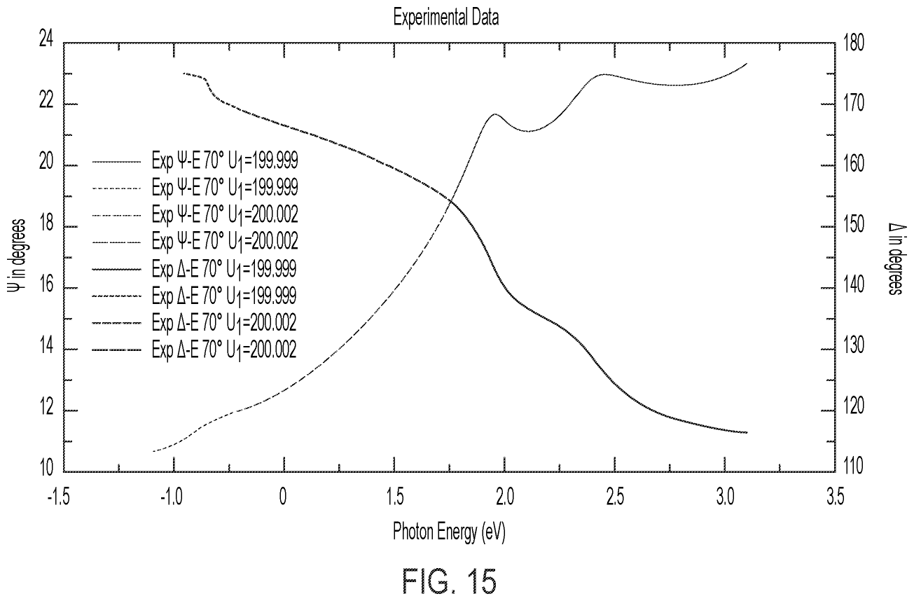

Process 1400 is shown to include measuring spectroscopic ellipsometry data at increasing temperature (1410). For example, the graph of FIG. 15 shows experimental spectroscopic ellipsometry data that can be measured as part of process 1400. In the graph of FIG. 15, both amplitude (Ψ) and phase (Δ) are plotted on the y-axis, and photon energy is plotted on the x-axis. The graph of FIG. 15 shows example spectroscopic ellipsometry data at a temperature of around 200° C., however process 1400 can include collecting spectroscopic ellipsometry data over a range of temperatures, such as covering a range from about 21° C.-380° C. In some cases, the range of temperatures over which spectroscopic ellipsometry data can be obtained is limited by the breakdown of the target semiconductor material. The temperature range can vary depending on the application and the specific target semiconductor material of interest. The graph of FIG. 15 shows example data where the target semiconductor material 120 is a gallium antimonide sample.

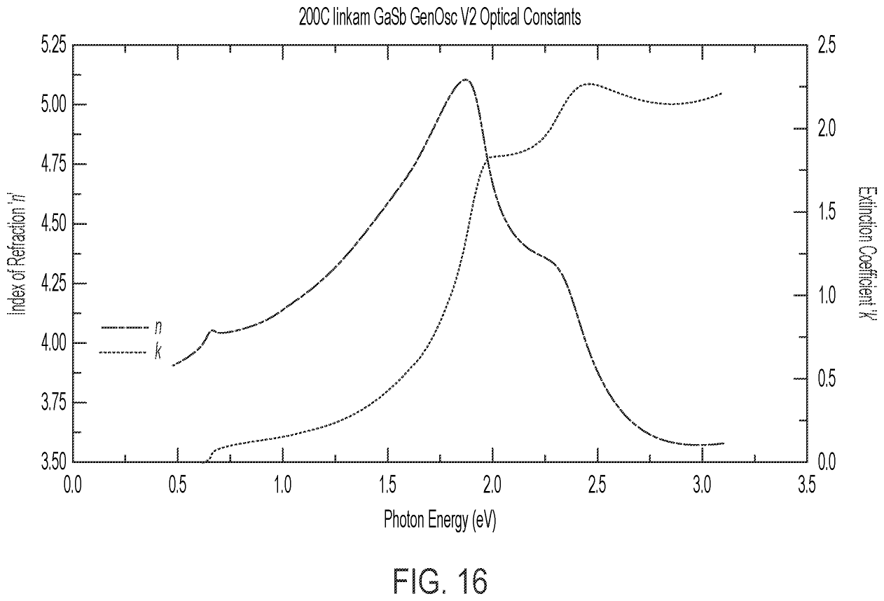

Process 1400 is also shown to include extracting optical constants from the spectroscopic ellipsometry data at each temperature (1420). For example, the graph of FIG. 16 shows optical constants that can be extracted as part of process 1400. In the graph of FIG. 16, optical constants n (index of refraction) and k (extinction coefficient) are plotted for the gallium antimonide sample over a broad spectral range at a specific temperature of around 200° C. Similar data can be obtained at each temperature of interest over a range of temperatures, such as the range from about 21° C.-380° C. However, depending on the application (e.g., for quantum material applications), this temperature range can be extended to higher and lower temperature ranges, including very low temperatures around −320° C. In the graph of FIG. 16 specifically, both optical constants (n and k) are plotted on the y-axis, and photon energy is plotted on the x-axis.

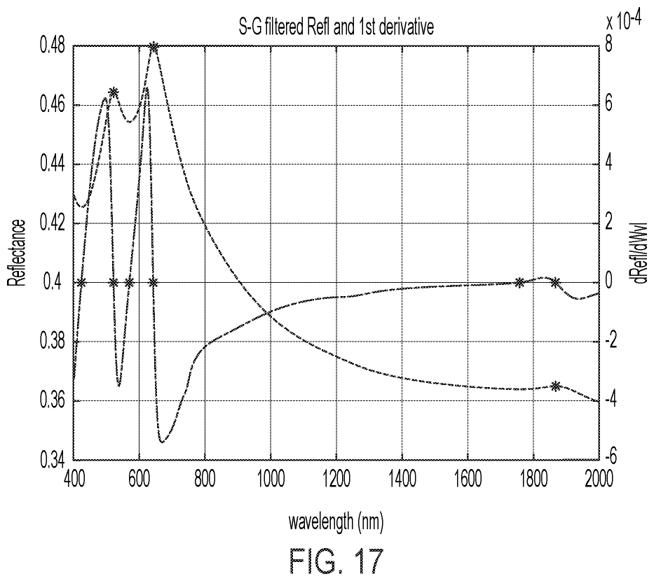

Process 1400 is also shown to include calculating reflectance and determining peak locations (1430). For example, the graph of FIG. 17 shows reflectance data that can be calculated as part of process 1400. In the graph of FIG. 17, both reflectance and the numerical first derivative of reflectance with respect to wavelength are plotted on the y-axis, whereas wavelength is plotted on the x-axis. The data shown in FIG. 17 is associated with an angle of incidence of 12°, however similar data can be obtained for any given angle of incidence to match the application. The reflectance spectrum shown in FIG. 17 can then be used to identify the location of spectral features (e.g., spectral feature 212 and spectral feature 214) indicative of the temperature of the gallium antimonide sample.

Process 1400 is also shown to include generating a peak location vs temperature curve (1440). For example, the graph of FIG. 10 shows an example peak location vs temperature curve that can be used as a calibration curve and generated using process 1400. In the graph of FIG. 10, the frontside temperature is plotted on the y-axis, and the peak location wavelength is plotted on the x-axis. Separate plots are shown for the locations where the numerical first derivative of the calculated reflectance data for the gallium antimonide sample is zero and the actual peak maxima locations, which are similar. A second-degree curve fit is also shown connecting the locations where the numerical first derivative of the calculated reflectance data for the gallium antimonide sample is zero. This calibration curve can be used to determine the temperature of any given gallium antimonide sample based on the location of one or more spectral features.

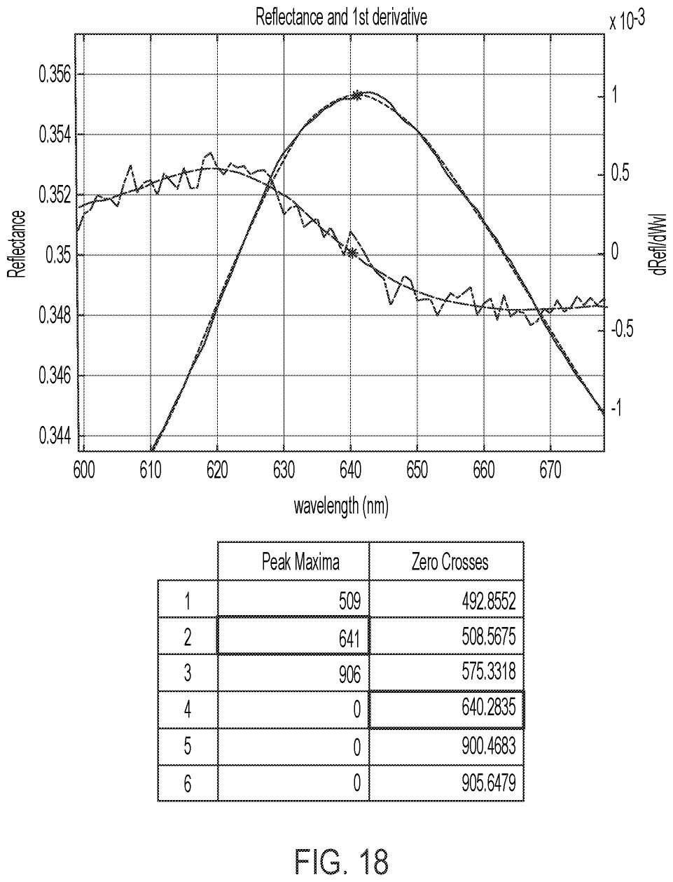

Referring to FIG. 18, a graph showing processed reflectance data and corresponding peak maxima and zero crosses is shown, in accordance with some embodiments of the present disclosure. In the graph of FIG. 18, both reflectance (left) and the numerical first derivative (right) of reflectance with respect to wavelength are plotted on the y-axis, whereas wavelength is plotted on the x-axis. The graph of FIG. 18 is generally a “zoomed in” version of the raw reflectance spectrum data shown in FIG. 12B for a gallium antimonide sample at around 200° C., also showing peak locations and zero crosses (locations where the numerical first derivative crosses zero). A first dotted line is shown in FIG. 18 representing filtered reflectance data, and a second dotted line is also shown in FIG. 18 representing filtered first derivative data. A script can be used to generate this filtered data, and to find the peak locations in the filtered reflectance data as well as the zero crosses in the filtered first derivative data. The script can be developed to automatically calculate an effective light source output given spectral reflectance data from a known reference and the known reflectivity of that sample, automatically calculate the reflectance spectrum of data from a sample of interest given the effective light source output, and take the reflectance spectrum, filter (e.g., using methods such as moving average and Savitzky-Golay), take the numerical first derivative of the data, and identify the location(s) of peaks in the data. Using scripts in this manner can increase the speed of the analysis and demonstrate how temperature measurement using process 300 could be automated in a software package for rapid temperature measurement during heating of a sample.

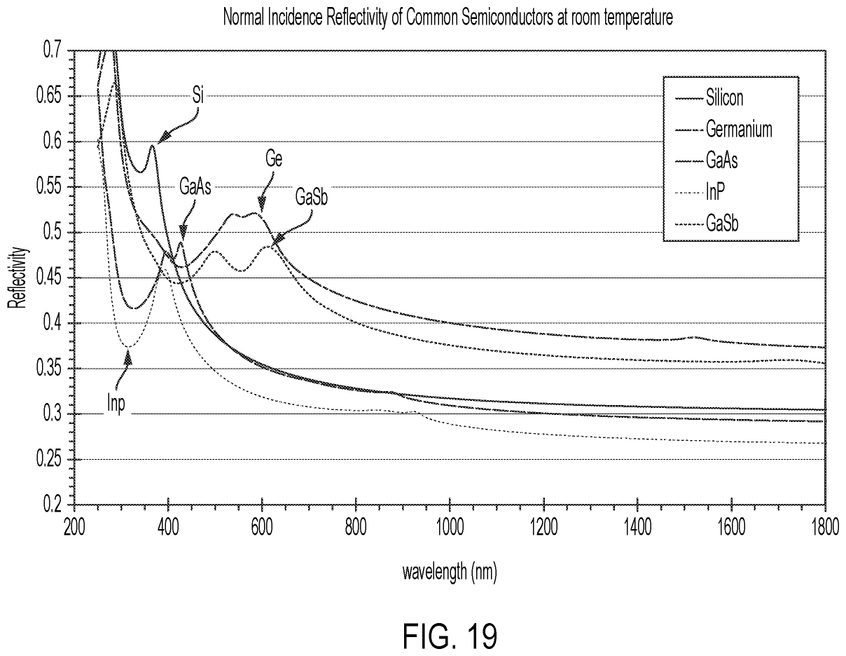

Referring to FIG. 19, an example graph of reflectivity data for different semiconductor materials is shown, in accordance with some embodiments of the present disclosure. In the graph of FIG. 19, reflectivity is plotted on the y-axis, whereas wavelength is plotted on the x-axis. The data shown in FIG. 19 is associated with a normalized angle of incidence, such as 12°, and is collected at room temperature. Reflectivity data is shown for different bulk materials that can be implementations of target semiconductor material 120, including silicon (Si), germanium (Ge), gallium arsenide (GaAs), indium phosphide (InP), and gallium antimonide (GaSb). FIG. 19 also shows the location of an above bang gap energy level spectral feature (e.g., spectral feature 212 and spectral feature 214) associated with each target semiconductor material, which generally are found at lower wavelengths as shown. The graph of FIG. 19 shows that, for a variety of different semiconductor materials, an above band gap spectral feature can be identified in the reflectance spectrum data. These spectral features can then be used to determine temperature of the semiconductor material, for example using process 300. While several different example semiconductor materials are shown in FIG. 19, the techniques described in the present disclosure are also applicable for materials that are not shown.

Referring to FIG. 20, an example table showing various data associated with different semiconductor materials is shown, in in accordance with some embodiments of the present disclosure. The table of FIG. 20 shows data for different implementations of target semiconductor material 120, including silicon (Si), germanium (Ge), gallium arsenide (GaAs), indium arsenide (InAs), gallium antimonide (GaSb), indium antimonide (InSb), indium phosphide (InP), and indium 0.53 gallium 0.47 arsenide (In0.53Ga0.47As). For each of these materials, the table of FIG. 20 shows a band gap energy level, a bandgap wavelength, a wavelength associated with a (first) spectral feature that is at an energy level above the band gap energy level (high energy) and an associated peak type, a wavelength associated with another (second) spectral feature that is at an energy level above the band gap energy level and an associated peak type, and an indication of whether the first spectral feature is clear and distinct. The data shown in the table of FIG. 20 is associated with room temperature and 0° (unpolarized) reflectance, however the peak locations do not vary with angle of incidence. The table of FIG. 20 provides an overview of how different reflectance characteristics vary for different semiconductor materials as relevant to the techniques described in the present disclosure.

System 100 and process 300 were further tested on samples of both germanium (Ge) and indium arsenide (InAs) as target semiconductor material 120. The results of the testing strongly suggest that process 300 can be implemented to accurately measure temperature of these different sample materials, in addition to gallium antimonide (GaSb) as detailed above.

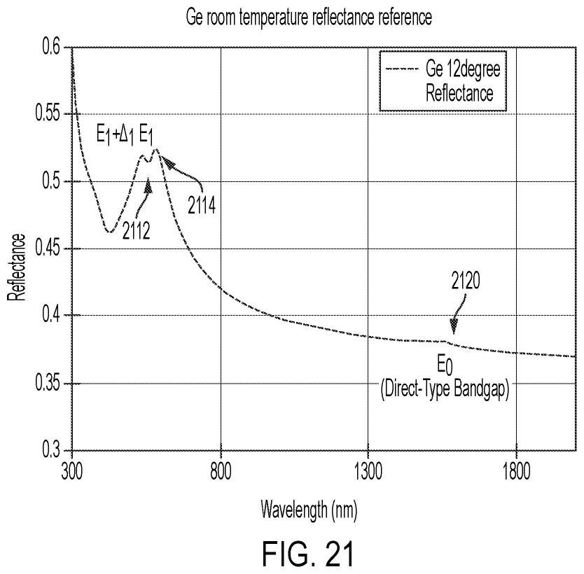

Referring to FIG. 21, a graph showing a spectral reflectance spectrum associated with a target semiconductor material of germanium at room temperature and a 12-degree angle of incidence is shown, in accordance with some embodiments of the present disclosure. The reflectance of the germanium material is plotted on the y-axis, and wavelength is plotted on the x-axis. In the graph of FIG. 21, two higher energy above band gap spectral features can be seen: both a spectral feature 2112 and a spectral feature 2114. Additionally, a lower energy bandgap spectral feature 2120 can also be seen in the graph of FIG. 21. The location of the above band gap (or higher order band transition) spectral features 2112 and 2114 have a repeatable dependence on temperature and are large features in the reflectance/reflectivity spectrum of germanium. Spectral feature 2114 as shown in FIG. 21 is found at an energy level E1, whereas spectral feature 2112 is found at an energy level with some delta with respect to E1, reflected as E1+A.

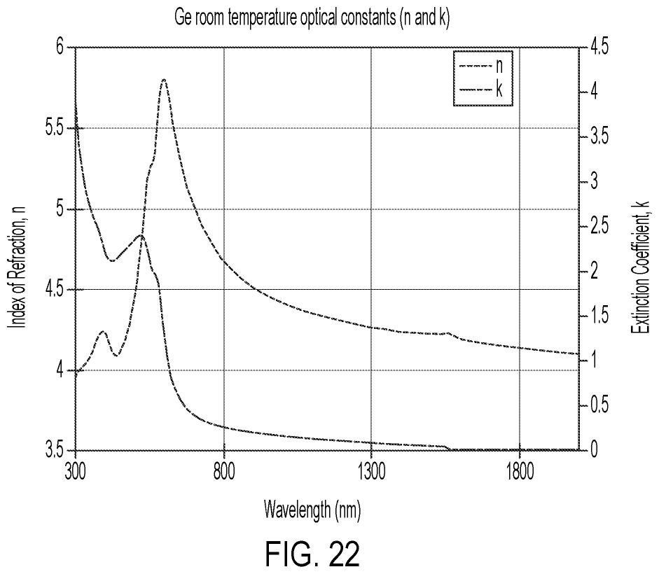

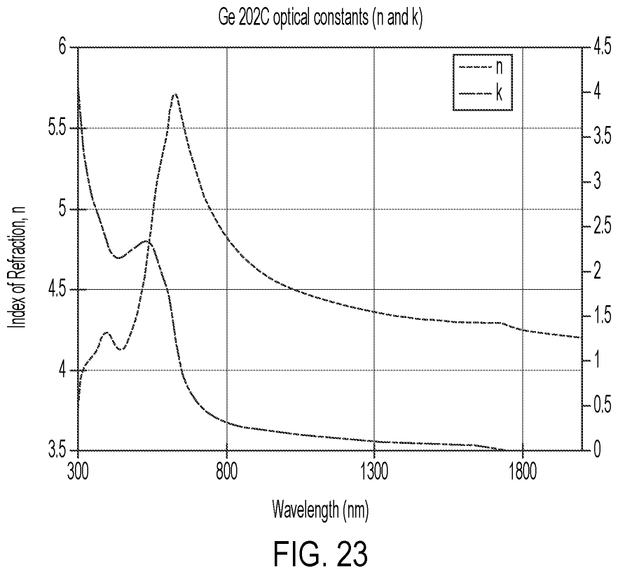

Referring to FIG. 22, a graph showing optical constants that can be extracted (e.g., as part of process 1400) from the germanium sample at room temperature is shown, in accordance with some embodiments of the present disclosure. In the graph of FIG. 22, optical constants n (index of refraction) and k (extinction coefficient) are plotted for the germanium sample over a broad spectral range. Referring to FIG. 23, a graph showing optical constants that can be extracted (e.g., as part of process 1400) from the germanium sample at a temperature of approximately 202° C. is shown, in accordance with some embodiments of the present disclosure. In the graph of FIG. 22, optical constants n and k are again plotted for the germanium sample over a broad spectral range.

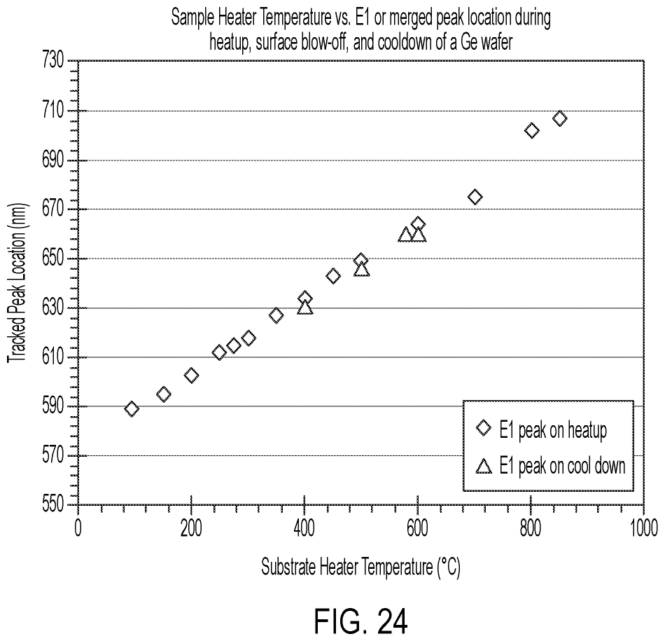

Referring to FIG. 24, an example graph showing peak location as a function of sample heater temperature for a germanium wafer is shown, in accordance with some embodiments of the present disclosure. In the graph of FIG. 24, the peak location wavelength is plotted on the y-axis, whereas the sample heater temperature (e.g., the temperature of sample heater 130) is plotted on the x-axis. Each plotted peak location corresponds to a point where the numerical first derivative of the calculated reflectance data for the germanium sample is zero at the given sample heater temperature. Separate plots are shown in FIG. 24 for the initial heat up of the germanium sample as well as the growth and cooling of the germanium sample. It can again be seen from the graph of FIG. 24 that the peak location (e.g., the location of the above band gap spectral features such as spectral feature 2112 or spectral feature 2114) does vary with temperature, and it does so in a generally linear relationship. This data is again indicative that the peak location found using the numerical first derivative of the calculated reflectance data for the germanium sample can be useful in measuring the temperature of the germanium sample.

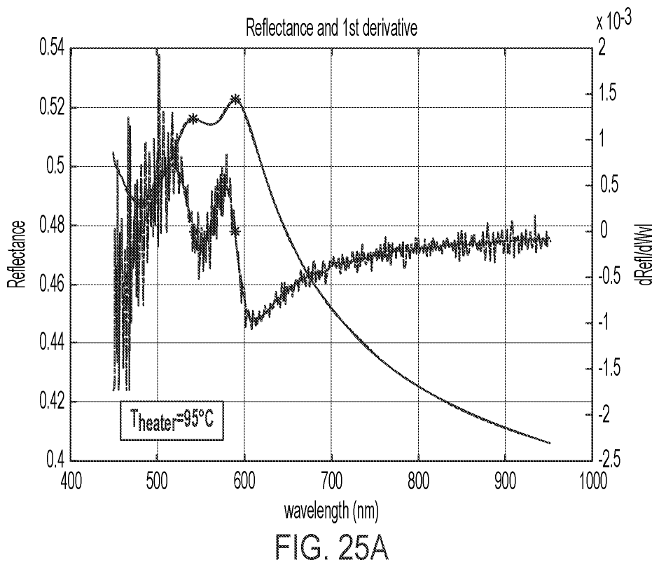

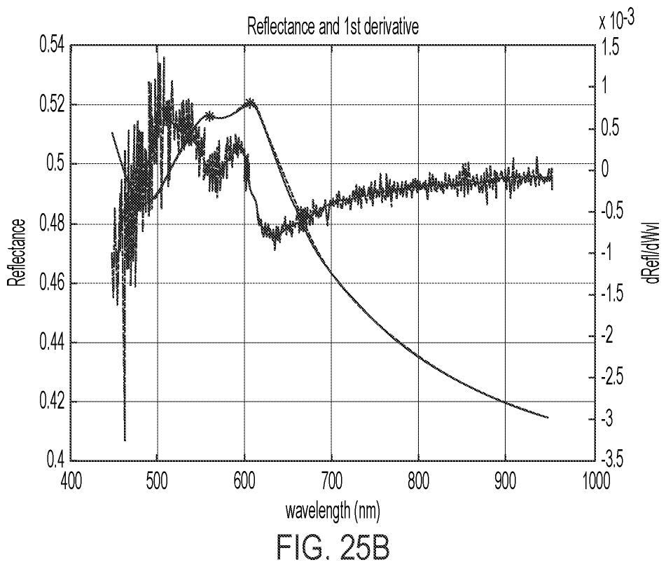

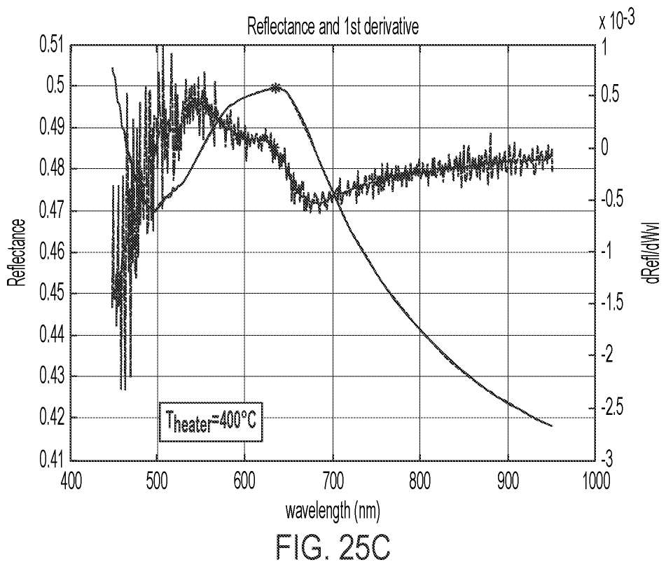

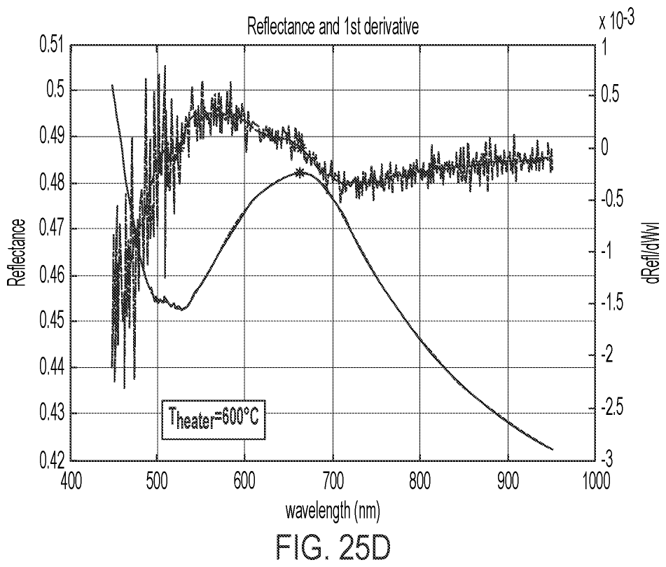

Referring to FIGS. 25A-25D, a series of graphs showing processed reflectance data obtained from a target semiconductor material at different temperatures is shown, in accordance with some embodiments of the present disclosure. The data shown in the graphs of FIGS. 25A-25D is associated with a germanium sample as the target semiconductor material. In the graphs of FIGS. 25A-25D, both the calculated reflectance data of the germanium sample and the calculated numerical first derivative of the calculated reflectance data of the germanium sample are plotted on the y-axis, and wavelength is plotted on the x-axis. The data shown in the graphs of FIGS. 25A-25D generally has been filtered, and a script has been used to identify locations of above band gap spectral features (such as spectral feature 2112 or spectral feature 2114). FIG. 25A shows data corresponding to a sample heater temperature of 95° C., FIG. 25B shows data corresponding to a sample heater temperature of 200° C., FIG. 25C shows data corresponding to a sample heater temperature of 400° C., and FIG. 25D shows data corresponding to a sample heater temperature of 600° C. It can be seen from the data shown in FIGS. 25A-25D that when using the reflectance analysis described in the present disclosure, the peak locations are clearly identifiable at each temperature. Some alternative approaches to measuring temperature of a target semiconductor material, in contrast, may be incapable or inaccurate at low temperatures.

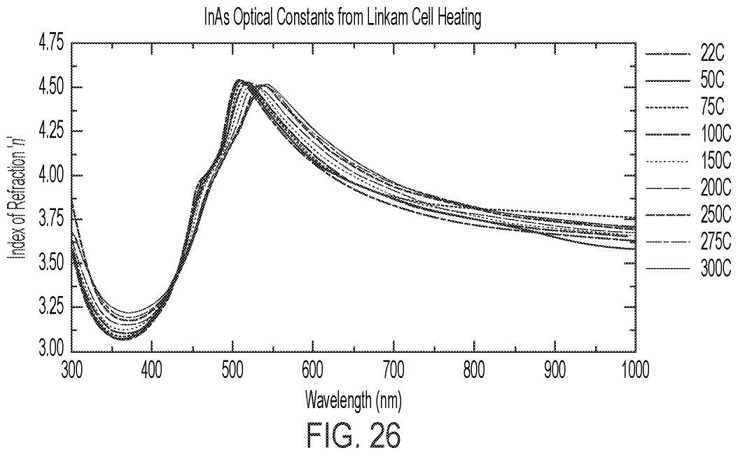

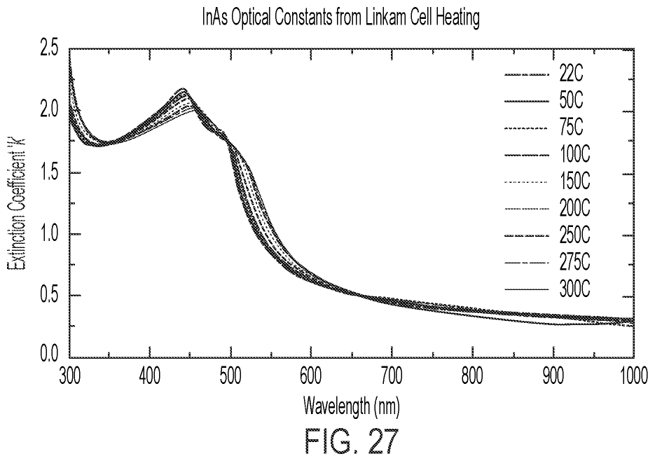

Referring to FIG. 26, an example graph showing an optical constant that can be extracted (e.g., as part of process 1400) from an indium arsenide sample is shown, in accordance with some embodiments of the present disclosure. In the graph of FIG. 26, the optical constant n (index of refraction) is plotted over a broad spectral range, at a variety of different temperatures. Referring to FIG. 27, an example graph showing another optical constant that can be extracted (e.g., as part of process 1400) from an indium arsenide sample is shown, in accordance with some embodiments of the present disclosure. In the graph of FIG. 27, the optical constant k (extinction coefficient) is plotted over a broad spectral range, at a variety of different temperatures. The data shown in the graphs of FIG. 26 and FIG. 27 is associated with ex-situ heating of an indium arsenide sample in the ellipsometer heating stage. The clear shifting in E1 and E1+Δ higher order critical point peaks that is visible in the graphs of FIG. 26 and FIG. 27 indicates that the spectral features can be used to accurately determine the temperature of the indium arsenide sample.

The present disclosure has described one or more preferred embodiments, and it should be appreciated that many equivalents, alternatives, variations, and modifications, aside from those expressly stated, are possible and within the scope of the invention.

1. A system comprising:
a light source;
a target semiconductor material;
a sensor that generates data responsive to acquiring light that is emitted by the light source and reflected from the target semiconductor material; and
one or more circuits configured to process the data generated by the sensor to determine a temperature of the target semiconductor material based on a location of a spectral feature, wherein the location of the spectral feature is at an energy level that is above a band gap energy level of the target semiconductor material.

2. The system of claim 1, wherein the one or more circuits are configured to calculate reflectance data for the light reflected from the target semiconductor material and to calculate a derivative of the reflectance data to identify the location of the spectral feature.

3. The system of claim 1, wherein the light acquired by the sensor is directly reflected from the target semiconductor material.

4. The system of claim 1, wherein the location of the spectral feature is at a band transition peak at the energy level that is above the band gap energy level of the target semiconductor material.

5. The system of claim 1, wherein the one or more circuits are configured to compare the location of the spectral feature to a calibration curve to determine the temperature of the target semiconductor material.

6. The system of claim 1, wherein the temperature of the target semiconductor material is below 300 degrees Celsius.

7. The system of claim 1, wherein the sensor comprises a spectrometer and the target semiconductor material comprises silicon, germanium, gallium arsenide, indium arsenide, gallium antimonide, indium antimonide, indium phosphide, or indium gallium arsenide.

8. A method comprising:
reflecting light from a target semiconductor material;
generating data comprising a reflectance spectrum responsive to acquiring the light reflected form the target semiconductor material;
processing the data to identify a location of a spectral feature within the reflectance spectrum that is indicative of a temperature of the target semiconductor material, wherein the location of the spectral feature is at an energy level that is above a band gap energy level of the target semiconductor material; and
determining the temperature of the target semiconductor material based on the location of the spectral feature.

9. The method of claim 8, wherein reflecting the light from the target semiconductor material comprises reflecting light that is emitted from a light source, the method further comprising comparing the light reflected from the target semiconductor material to a previous output of the light source to generate the data comprising the reflectance spectrum.

10. The method of claim 8, further comprising calculating a derivative of the reflectance spectrum to identify the location of the spectral feature within the reflectance spectrum.

11. The method of claim 8, wherein acquiring the light reflected from the target semiconductor material comprises acquiring light that is directly reflected from the target semiconductor material.

12. The method of claim 8, wherein determining the temperature of the target semiconductor material based on the location of the spectral feature comprises comparing the location of the spectral feature to a calibration curve.

13. The method of claim 8, wherein determining the temperature of the target semiconductor material based on the location of the spectral feature comprises determining that the temperature of the target semiconductor material is below 300 degrees Celsius.

14. The method of claim 8, wherein processing the data to identify the location of the spectral feature comprises identifying a band transition peak at the energy level that is above the band gap energy level of the target semiconductor material.

15. A method comprising:
reflecting light from a target semiconductor material;
generating data responsive to acquiring the light reflected from the target semiconductor material;
processing the data to identify a location of a spectral feature, wherein the location of the spectral feature is at an energy level that is above a band gap energy level of the target semiconductor material; and
determining a temperature of the target semiconductor material based on the location of the spectral feature.

16. The method of claim 15, wherein reflecting the light from the target semiconductor material comprises reflecting light that is emitted from a light source, the method further comprising comparing the light reflected from the target semiconductor material to a previous output of the light source to generate the data.

17. The method of claim 15, wherein acquiring the light reflected from the target semiconductor material comprises acquiring light that is directly reflected from the target semiconductor material.

18. The method of claim 15, wherein determining the temperature of the target semiconductor material based on the location of the spectral feature comprises comparing the location of the spectral feature to a calibration curve.

19. The method of claim 15, wherein generating the data responsive to acquiring the light reflected from the target semiconductor material comprises generating data comprising a reflectance spectrum.

20. The method of claim 15, further comprising calculating a derivative of the data to identify the location of the spectral feature within the reflectance spectrum.
